(19) United States
(12) Patent Application Publication
(10) Pub. No.: US 2025/0098188 A1
(43) Pub. Date: Mar. 20, 2025

(54) SYMMETRICAL 3D BIPOLAR NANOSHEET TRANSISTOR

(71) Applicant: Tokyo Electron Limited, Tokyo (JP)

(72) Inventors: Henry Jim FULFORD, Albany, NY (US); Mark I. GARDNER, Albany, NY (US)

(73) Assignee: Tokyo Electron Limited, Tokyo (JP)

(21) Appl. No.: 18/597,762

(22) Filed: Mar. 6, 2024

Related U.S. Application Data
(60) Provisional application No. 63/539,576, filed on Sep. 20, 2023.

(51) Int. Cl. H01L 29/73; H01L 29/06; H01L 29/08; H01L 29/10; H01L 29/66

(52) U.S. Cl. CPC H10D 10/00; H10D 10/01; H10D 62/121; H10D 62/133; H10D 62/137; H10D 62/177

(57) ABSTRACT

Semiconductor devices and corresponding methods of manufacture are disclosed. The method includes forming vertical channel structures on a substrate. The vertical channel structures are formed within a layer stack of alternating layers of a first metal and a first dielectric. The vertical channel structures are channels of field effect transistors that have a current flow path perpendicular to a surface of the substrate. The vertical channel structures have a dielectric core. The method includes forming openings on the substrate that uncover a region of the layer stack adjacent to the vertical channel structures. The method includes, for each vertical channel structure, forming a corresponding staircase region in the layer stack, and forming metal contacts within each staircase region.

### CROSS-REFERENCE TO RELATED APPLICATIONS

This application claims priority to U.S. Provisional Application No. 63/539,576, filed Sep. 20, 2023, which is incorporated by reference in its entirety.

### FIELD OF THE DISCLOSURE

This disclosure relates to microelectronic devices including semiconductor devices, transistors, and integrated circuits, including methods of microfabrication.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate. Historically, with microfabrication, transistors have been created in one plane, with wiring or metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits.

### SUMMARY

The techniques described herein include methods and devices for 3D fabrication of semiconductor devices. Specifically, techniques disclosed herein include forming three-dimensional (3D) bipolar nanosheet transistors. The methods, structures, techniques described herein allow for improved performance of devices with a reduced circuit area.

One aspect of the present disclosure is directed to a semiconductor device. The semiconductor device includes a first semiconductor structure including a lower portion and an upper portion, wherein the first semiconductor structure has a first conductive type; a second semiconductor structure in contact with the lower portion of the first semiconductor structure, wherein the second semiconductor structure has a second conductive type opposite to the first conductive type; and a third semiconductor structure in contact with the lower portion of the first semiconductor structure, wherein the third semiconductor structure has the second conductive type. The second semiconductor structure and the third semiconductor structure laterally extend toward opposite directions.

Another aspect of the present disclosure is directed to a first semiconductor structure having a first conductive type, the first semiconductor structure comprising an upper portion and a lower portion; a second semiconductor structure having a second conductive type opposite to the first conductive type; a third semiconductor structure having the second conductive type. The lower portion of the first semiconductor structure is disposed between the second semiconductor structure and the third semiconductor structure and is in electrical contact with the second semiconductor structure and the third semiconductor structure.

Yet another aspect of the present disclosure is directed to a method for fabricating semiconductor devices. The method includes forming a lower portion of a first semiconductor structure vertically interposed between a first dielectric structure and a second dielectric structure; epitaxially growing a second semiconductor structure and a third semiconductor structure from the lower portion of the first semiconductor structure; forming a first metal structure and a second metal structure to contact the second semiconductor structure and the third semiconductor structure, respectively; and forming an upper portion of the first semiconductor structure that extends through at least the second dielectric structure.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flow chart of an example method for manufacturing a semiconductor structure, according to some embodiment.

FIG. 2 illustrates a flow chart of an example method for manufacturing a semiconductor structure, according to some embodiment.

FIGS. 3 to 16 illustrate cross-sectional or top views of an example semiconductor structure, made by the method shown in FIG. 1, during various stages of fabrication, according to some embodiments.

FIGS. 17 to 20 illustrate cross-sectional or top views of an example semiconductor structure, made by the method shown in FIG. 2, during various stages of fabrication, according to some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Techniques herein include methods and devices for 3D bipolar nanosheet transistors. Specifically, techniques include forming horizontal 3D bipolar nanosheet transistors. In some examples, the transistors are formed symmetrically. In some examples, a number of the transistors (e.g., N transistors) may be stacked. Using a circuit layout where a stack of devices (e.g., emitters, collectors, and base regions of the 3D bipolar nanosheet transistor are connected together) provides improved performance of devices with a reduced circuit area. The techniques disclosed herein include all 3D bipolar nanosheet transistors (e.g., NPN, PNP). The techniques disclosed herein can be integrated with 3D nanosheet formation for logic and memory devices. The techniques disclosed herein further demonstrate improved performance of devices by utilizing epitaxial semiconductor structures. For example, single crystal epitaxial semiconductor structures can be used to fabricate an NPN and a PNP 3D stacked bipolar devices. Furthermore, the techniques disclosed herein include forming an epitaxial structure to vertically expand a base structure to a top surface of the 3D device architecture. In some examples, the epitaxial structure to vertically expand a base structure can be formed using a maskless self-aligned method.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

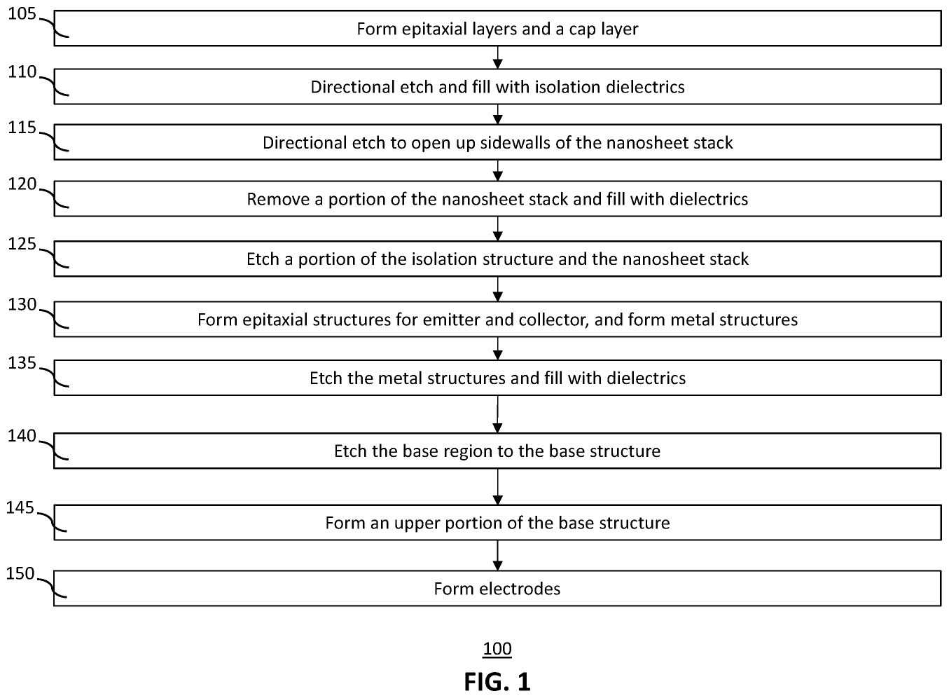

FIG. 1 illustrates a flow chart of an example method 100 for fabricating a semiconductor device, in accordance with some embodiments. It is noted that the method 100 is merely an example and is not intended to limit the present disclosure. Accordingly, it is understood that additional operations may be provided before, during, and after the method 100 of FIG. 1, that any operation may be omitted, and that some other operations may only be briefly described herein.

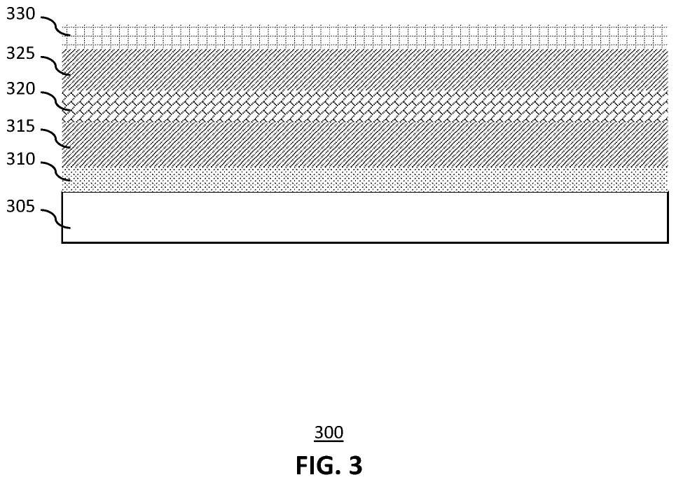

In various embodiments, operations of the method 100 may be associated with cross-sectional views of an example structure at various fabrication stages as shown in FIGS. 3 to 16, which will be discussed in further detail below. It should be understood that the structure, shown in FIGS. 3 to 16, may include a number of other structures, while remaining within the scope of the present disclosure.

In brief overview, the method 100 starts with operation 105 of forming epitaxial layers and a cap layer. The method 100 continues to operation 110 of directionally etching and filling with isolation dielectrics. The method 100 continues to operation 115 of directionally etching to open up sidewalls of the nanosheet stack. The method 100 continues to operation 120 of removing a portion of the nanosheet stack and filling with dielectrics. The method 100 continues to operation 125 of etching a portion of the isolation structure and the nanosheet stack. The method 100 continues to operation 130 of forming epitaxial structures for emitter and collector and forming metal structures. The method 100 continues to operation 135 of etching the metal structures and filling with dielectrics. The method 100 continues to operation 140 of etching the base region to the base structure. The method 100 continues to operation 145 of forming an upper portion of the base structure. The method 100 continues to operation 150 of forming electrodes.

Corresponding to operation 105 of the method 100 in FIG. 1, FIG. 3 is a cross-sectional view of an example semiconductor structure 300 in which a first epitaxial layer 310, a second epitaxial layer 315, a base epitaxial layer 320, a third epitaxial layer 325, and a cap layer 330 are formed over a substrate 305, in accordance with various embodiments.

The substrate 305 may be a semiconductor substrate, such as a bulk semiconductor, a semiconductor-on-insulator (SOI) substrate, or the like, which may be doped (e.g., with a p-type or an n-type dopant) or undoped. The substrate 305 may be a wafer, such as a silicon wafer. Other substrates, such as a multi-layered or gradient substrate may also be used. In another example, the substrate 305 may be an intermetal dielectric (e.g., silicon oxide or otherwise low-k dielectric material). In yet another example, the substrate 305 may be a portion of a 3D NAND memory device, and the substrate 305 may include a stack of different dielectric materials (e.g., oxide-nitride-oxide-nitride (ONON)) alternately arranged on top of one another. The thickness of such a stack layer may vary. For example, the thickness of the ONON layer may be around 8 μm.

The substrate 305 includes a semiconductor material, such as a bulk semiconductor, a semiconductor-on-insulator (SOI), or the like, which may be doped (e.g., with a p-type or an n-type dopant) or undoped. The substrate 305 may be or correspond to a wafer, such as a silicon wafer. Generally, an SOI includes a layer of a semiconductor material formed on an insulator layer. The insulator layer may be, for example, a buried oxide (BOX) layer, a silicon oxide layer, or the like. The substrate 305 may include other semiconductor materials, such as a multi-layered or gradient semiconductor material. In some examples, the substrate 305 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

As shown in FIG. 3, the first epitaxial layer 310, the second epitaxial layer 315, the base epitaxial layer 320, and the third epitaxial layer 325 can be formed over the substrate 305. One or more of the first epitaxial layer 310, the second epitaxial layer 315, the base epitaxial layer 320, the third epitaxial layer 325, and various additional dielectric and conductive layers and materials herein can be placed, grown, (e.g., epitaxially with or without a seed layer), or otherwise formed to create layers of the structure 300.

The first epitaxial layer 310 can be or include a material which can be selectively etched, relative to one or more adjacent materials, such as the substrate 305. The first epitaxial layer 310 may be or include silicon, doped silicon, or any other semiconductor material that allows for epitaxial growth of the second epitaxial layer 315. The first epitaxial layer 310 may be formed or deposited using at least one suitable deposition technique, such as chemical vapor deposition (CVD), atomic layer deposition (ALD), molecular beam epitaxy (MBE), the like, or combinations thereof. Likewise, the second epitaxial layer 315 can be or include a material which can be selectively etched, relative to one or more adjacent materials, such as the first epitaxial layer 310 and/or the base epitaxial layer 320. The second epitaxial layer 315 may be or include silicon, doped silicon, or any other semiconductor material that allows for epitaxial growth of the base epitaxial layer 320. The second epitaxial layer 315 may be formed or deposited using at least one suitable deposition technique, such as chemical vapor deposition (CVD), atomic layer deposition (ALD), molecular beam epitaxy (MBE), the like, or combinations thereof.

The base epitaxial layer 320 can be or include a material which can be selectively etched, relative to one or more adjacent materials, such as the second epitaxial layer 315 and/or the third epitaxial layer 325. The base epitaxial layer 320 may be or include silicon, doped silicon, or any other semiconductor material that allows for epitaxial growth of the third epitaxial layer 325. The base epitaxial layer 320 may be formed or deposited using at least one suitable deposition technique, such as chemical vapor deposition (CVD), atomic layer deposition (ALD), molecular beam epitaxy (MBE), the like, or combinations thereof. The base epitaxial layer 320 has a first conductive type. For example, the base epitaxial layer 320 is an n-type (or p-type) semiconductor layer. As will be discussed below, at least a portion of the base epitaxial layer 320 may be configured as the base terminal of a corresponding bipolar junction transistor (BJT) device.

The third epitaxial layer 325 can be or include a material which can be selectively etched, relative to one or more adjacent materials, such as the base epitaxial layer 320. The third epitaxial layer 325 may be or include silicon, doped silicon, or any other semiconductor material. The third epitaxial layer 325 may be formed of a material the same as of the second epitaxial layer 315. The third epitaxial layer 325 may be formed or deposited using at least one suitable deposition technique, such as CVD, ALD, MBE, the like, or combinations thereof.

The cap layer 330 can be formed (e.g., deposited) over the third epitaxial layer 325. The cap layer 330 can be a protectant from environmental or processing operations (e.g., the methods disclosed herein). For example, the cap layer 330 can be a hard mask including a suitable dielectric material, such as silicon oxide, silicon nitride, or the like. The cap layer 330 may be formed or deposited using at least one suitable deposition technique, such as CVD, flowable CVD (FCVD), ALD, spin coating, the like, or combinations thereof.

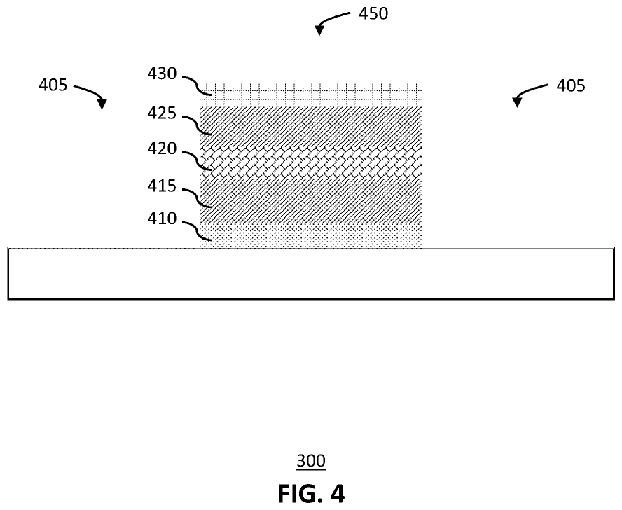

Corresponding to operation 110 of the method 100 in FIG. 1, FIG. 4 is a cross-sectional view of the example semiconductor structure 300 in which portions 405 are directionally etched and a nanosheet stack 450 is formed, in accordance with various embodiments.

A mask (not shown) can define the portions 405 of the structure 300 to be etched and a portion to remain to form the nanosheet stack 450. The nanosheet stack 450 includes a first epitaxial structure 410, a second epitaxial structure 415, a base epitaxial structure 420, a third epitaxial structure 425, and a cap structure 430.

To etch the portions 405, a patternable layer (e.g., a photoresist material) can be formed over the surface of the structure 300 (e.g., the surface of the cap layer 330). The layers of the structure 300 in the portions 405 can be etched to a depth of the substrate 305. For example, the etchant can be timed to etch to the substrate 305, the substrate 305 can be non-reactive with the etchant, or an etch stop layer can be disposed along a surface of the substrate 305. The etching process may be anisotropic and/or isotropic. The photoresist material can be stripped from the structure 300 after the etching process.

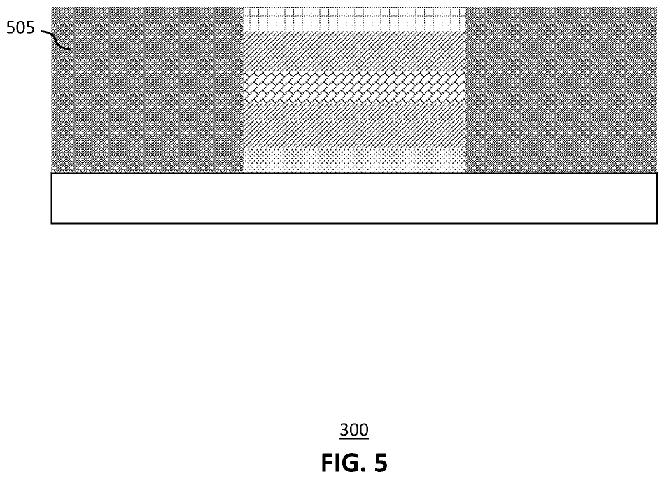

Still corresponding to operation 110 of the method 100 in FIG. 1, FIG. 5 is a cross-sectional view of the example semiconductor structure 300 in which isolation structures 505 are formed over the portions 405, in accordance with various embodiments.

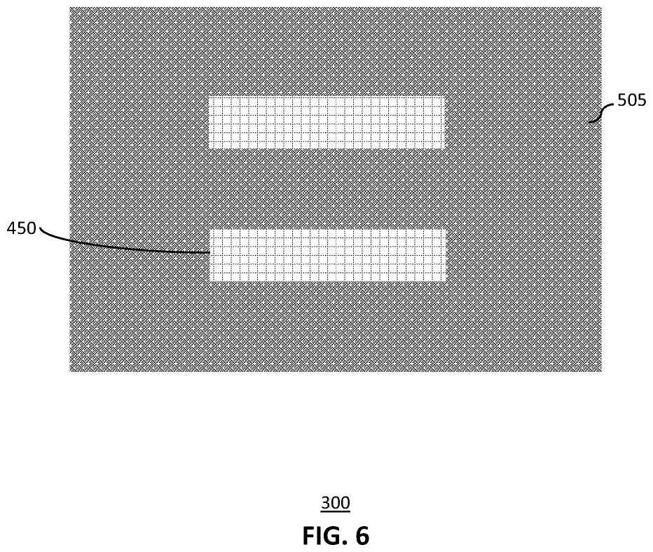

The isolation structures 505 may be or include a dielectric material to isolate the nanosheet stack 450. The isolation structures 505 can be formed by any deposition process or any fill process. Any portion of the isolation structures 505 and/or any dielectric disposed over a level above the cap structure 430 can be removed by a planarization process such as CMG/P. FIG. 6 is a top view of the structure 300 depicted in FIG. 5, in accordance with various embodiments. Although two of the nanosheet stack 450 are shown in FIG. 6, any number of nanosheet stacks can be formed in the structure 300.

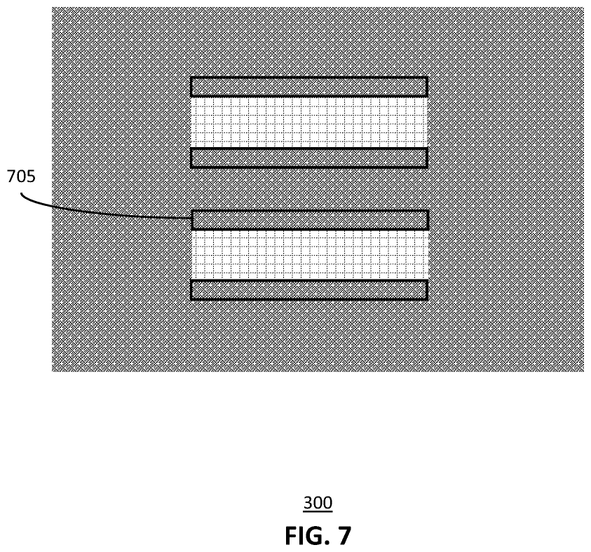

Corresponding to operation 115 of the method 100 in FIG. 1, FIG. 7 is a cross-sectional view of the example semiconductor structure 300 in which portions 705 are directionally etched to open up at least a portion of sidewalls of the nanosheet stack 450, in accordance with various embodiments. To etch the portions 705, a patternable layer (e.g., a photoresist material) to define the sidewalls of the nanosheet stack 450 can be formed over the surface of the structure 300. The layers of the structure 300 in the portions 705 can be etched to an etch depth between the surface of the substrate 305 and the height of the first epitaxial structure 410. For example, the etchant can be timed to etch to the etch depth, or an etch stop layer can be disposed. The photoresist material can be stripped from the structure 300 after the etching process. As shown, residual portions of the isolation structures 505 can remain over the portions 705.

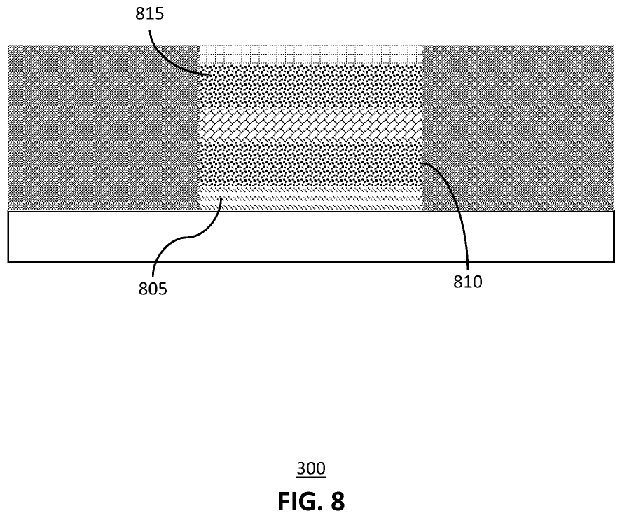

Corresponding to operation 120 of the method 100 in FIG. 1, FIG. 8 is a cross-sectional view of the example semiconductor structure 300 in which a portion of the nanosheet stack 450 is removed and filed with dielectrics, in accordance with various embodiments.

The first epitaxial structure 410 can be removed (e.g., etched) through the portions 705. For example, an etchant can be used to selectively etch the first epitaxial structure 410 without affecting and/or etching adjacent materials (e.g., the substrate 305, the second epitaxial structure 415, etc.). Following the removal of the first epitaxial structure 410, a first dielectric 805 can be formed. The first dielectric 805 can be formed by any deposition process or any fill process.

The second epitaxial structure 415 can be removed (e.g., etched) through the portions 705. For example, an etchant can be used to selectively etch the second epitaxial structure 415 without affecting and/or etching adjacent materials (e.g., the first epitaxial structure 410, the first dielectric 805, the base epitaxial structure 420, etc.). Following the removal of the second epitaxial structure 415, a second dielectric 810 can be formed. The second dielectric 810 can be formed by any deposition process or any fill process. Likewise, the third epitaxial structure 425 can be removed (e.g., etched) through the portions 705. For example, an etchant can be used to selectively etch the third epitaxial structure 425 without affecting and/or etching adjacent materials (e.g., the base epitaxial structure 420, etc.). Following the removal of the third epitaxial structure 425, a third dielectric 815 can be formed. The third dielectric 815 can be formed by any deposition process or any fill process. In some examples, the second epitaxial structure 415 and the third epitaxial structure 425 can be etched at the same time. In some examples, the second dielectric 810 and the third dielectric 815 can be formed at the same time.

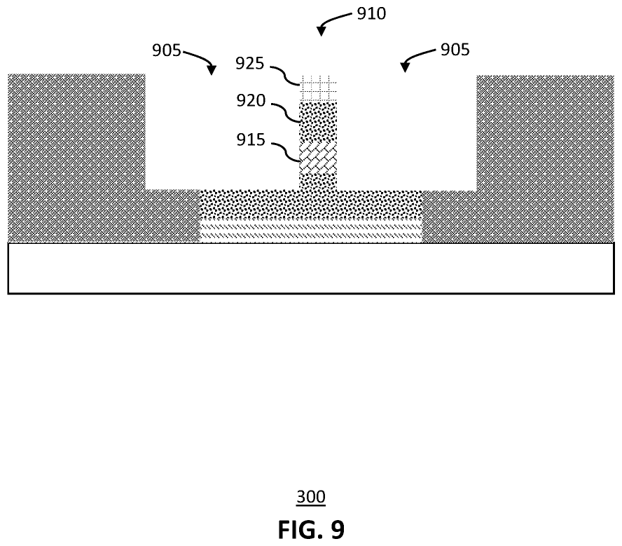

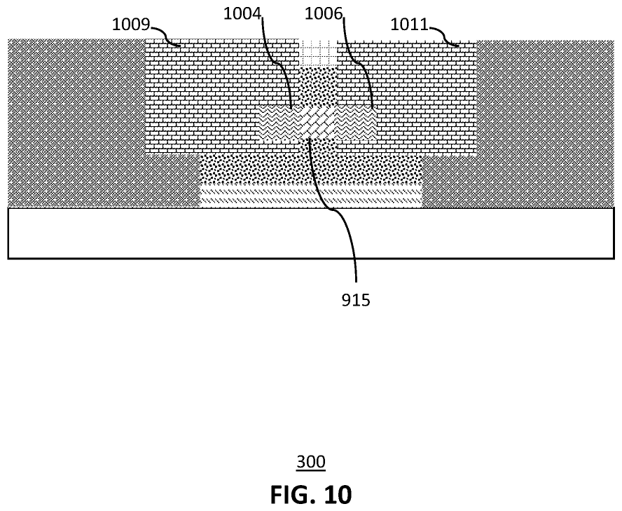

Corresponding to operation 125 of the method 100 in FIG. 1, FIG. 9 is a cross-sectional view of the example semiconductor structure 300 in which portions 905 of the isolation structures 505 and the nanosheet stack 450 are etched and a nanostructure 910 is formed, in accordance with various embodiments. The nanostructure 910 includes a lower portion 915, a dielectric portion 920, and a cap portion 925. The lower portion 915 is “floating” (electrically isolated by the underlying layer, e.g., the second dielectric 810), which allows epitaxial structures formed thereon (e.g., 1004, 1006 in FIG. 10) to float.

A mask (not shown) can define the portions 905 of the structure 300 to be etched and a portion to remain to form the nanostructure 910. To etch the portions 905, a patternable layer (e.g., a photoresist material) can be formed over the surface of the structure 300. As shown, the portions 905 can be etched to a depth between the surface of the first dielectric 805 and the surface of the second dielectric 810. For example, the etchant can be timed to etch to the depth between the surface of the first dielectric 805 and the surface of the second dielectric 810. The photoresist material can be stripped from the structure 300 after the etching process.

As shown, at least a portion of the isolation structures 505, at least a portion of the first dielectric 805, at least a portion of the second dielectric 810, at least a portion of the base epitaxial structure 420, at least a portion of the third dielectric 815, and at least a portion of the cap structure 430 are removed in the portions 905.

Corresponding to operation 130 of the method 100 in FIG. 1, FIG. 10 is a cross-sectional view of the example semiconductor structure 300 in which an emitter epitaxial structure 1004 and a collector epitaxial structure 1006 are formed, and a first metal structure 1009 and a second metal structure 1011 are formed over the emitter epitaxial structure 1004 and the collector epitaxial structure 1006, respectively, in accordance with various embodiments. For example, the first metal structure 1009 can surround the emitter epitaxial structure 1004 except for the side in connection with the lower portion 915, and the second metal structure 1011 can surround the collector epitaxial structure 1006 except for the side in connection with the lower portion 915.

The emitter and collector epitaxial structures 1004, 1006 may be or include silicon, doped silicon, or any other semiconductor material that can be epitaxially grown from and/or on the lower portion 915. As such, the emitter epitaxial structure 1004 and the collector epitaxial structure 1006 can laterally extend from the lower portion 915. Further, the emitter epitaxial structure 1004 and the collector epitaxial structure 1006 can extend toward opposite lateral directions, in some embodiments. The emitter and collector epitaxial structures 1004, 1006 may be formed or deposited using at least one suitable deposition technique, such as CVD, ALD, MBE, the like, or combinations thereof. For example, the emitter and collector epitaxial structures 1004, 1006 can be epitaxially grown on the lower portion 915 in the lateral direction with respect to the lower portion 915. For example, each of the emitter and collector epitaxial structures 1004, 1006 has a sidewall that shares with and is in direct contact with the lower portion 915. The emitter and collector epitaxial structures 1004, 1006 have a second conductive type, opposite to the first conductive type of the lower portion 915. For example, the emitter and collector epitaxial structures 1004, 1006 have a p-type (or n-type) semiconductor structure. As such, a pair of p-n junctions can be formed, e.g., one of which is formed between the emitter epitaxial structure 1004 and the lower portion 915, and the other of which is formed between the collector epitaxial structure 1006 and the lower portion 915.

The first and second metal structures 1009, 1011 may be or include any metal to form emitter and collector metal structures. The first and second metal structures 1009, 1011 can be formed by any deposition process or any metal fill process. The first and second metal structures 1009, 1011 can be formed such that the first metal structure 1009 is in contact with a top surface, a bottom surface, and a first sidewall of the emitter epitaxial structure 1004 and that the second metal structure 1011 is in contact with a top surface, a bottom surface, and a first sidewall of the collector epitaxial structure 1006. The first and second metal structures 1009, 1011 can be in electrical contact with the emitter and collector epitaxial structures 1004, 1006, respectively. The first and second metal structures 1009, 1011 are electrically isolated from the lower portion 915 (e.g., isolated at least by the emitter and collector epitaxial structures 1004, 1006). Any portion of the first and second metal structures 1009, 1011 and/or any metal disposed over a level above the cap portion 925 can be removed by a planarization process such as CMG/P. Although not shown here, in some examples, two emitters and two collectors can be shorted together to enhance device performance with a smaller area.

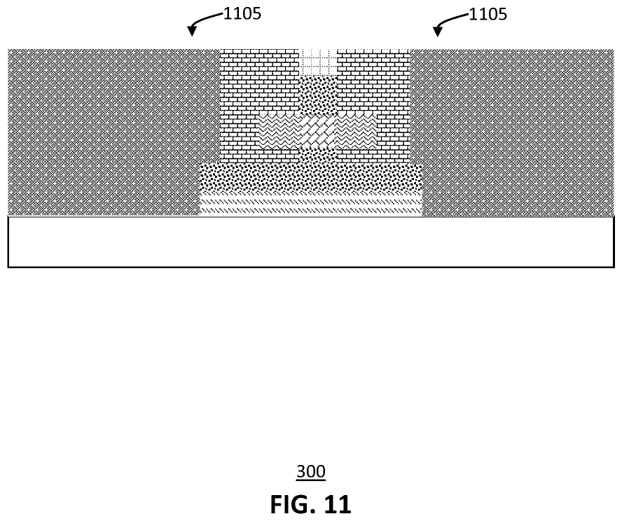

Corresponding to operation 135 of the method 100 in FIG. 1, FIG. 11 is a cross-sectional view of the example semiconductor structure 300 in which portions 1105 of the first and second metal structures 1009, 1011 are etched and filled with dielectrics, in accordance with various embodiments.

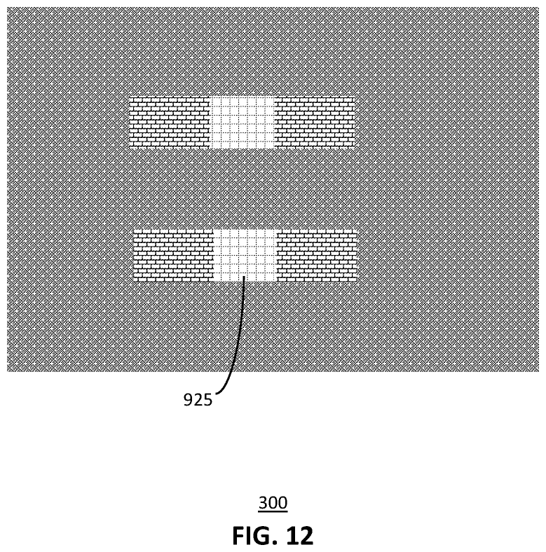

A mask (not shown) can define the portions 1105 of the structure 300 to be etched. To etch the portions 1105, a patternable layer (e.g., a photoresist material) can be formed over the surface of the structure 300. The layers of the structure 300 in the portions 1105 (e.g., at least a portion of the first and second metal structures 1009, 1011) can be etched, and the mask (e.g., a photoresist material) can be stripped from the structure 300 after the etching process. The portions 1105 that have been etched can be filled with dielectrics. As shown, the etched portions 1105 can be filled with the dielectric material the same as of the isolation structures 505, thereby reducing the first and second metal structures 1009, 1011. The portions 1105 can be filled with the dielectrics by any deposition process or any fill process. Any portion of the dielectrics (or the isolation structures 505) disposed over a level above the cap portion 925 can be removed by a planarization process such as CMG/P. FIG. 12 is a top view of the structure 300 depicted in FIG. 11, in accordance with various embodiments.

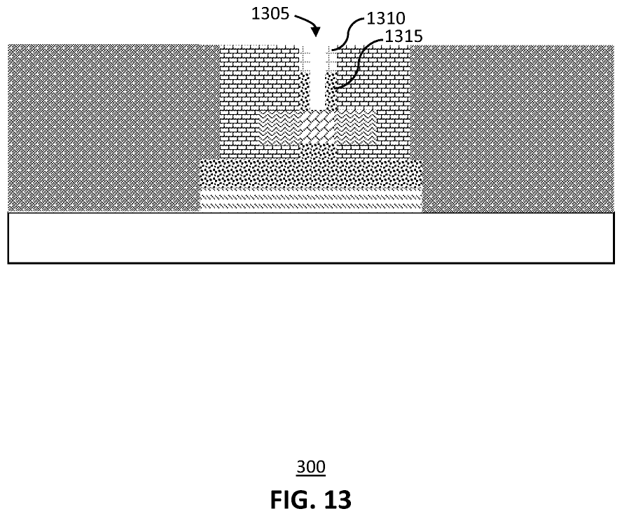

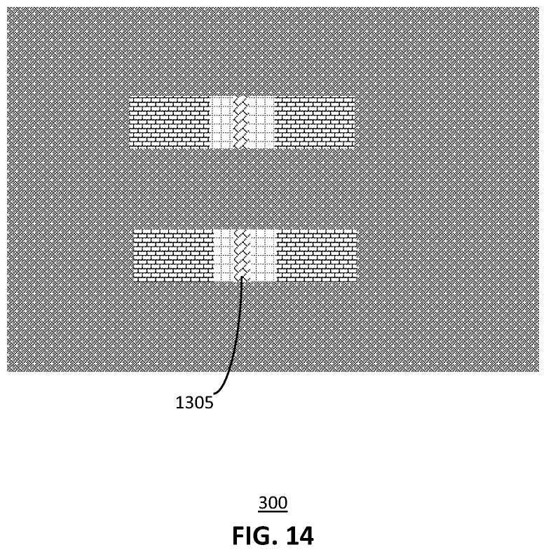

Corresponding to operation 140 of the method 100 in FIG. 1, FIG. 13 is a cross-sectional view of the example semiconductor structure 300 in which a base region 1305 is etched, in accordance with various embodiments. A mask (not shown) can define the base region 1305 to be etched. To etch the base region 1305, a patternable layer (e.g., a photoresist material) can be formed over the surface of the structure 300. The layers of the structure 300 in the base region 1305 (e.g., at least a portion of the cap portion 925 and the dielectric portion 920) can be etched, and the mask (e.g., a photoresist material) can be stripped from the structure 300 after the etching process. The base region 1305 can be etched to the surface of the lower portion 915. For example, the etchant can be timed to etch to the surface of the lower portion 915, the lower portion 915 can be non-reactive with the etchant, or an etch stop layer can be pre-disposed along a surface of the lower portion 915. The mask (e.g., a photoresist material) can be stripped from the structure 300 after the etching process. FIG. 14 is a top view of the structure 300 depicted in FIG. 13, in accordance with various embodiments. Now the etched portion of the cap portion 925 is referred to as an etched cap portion 1310, and the etched portion of the dielectric portion 920 is referred to as an etched dielectric 1315.

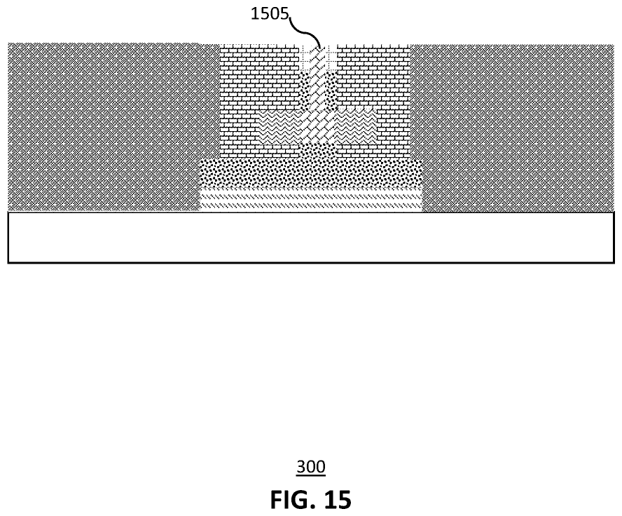

Corresponding to operation 145 of the method 100 in FIG. 1, FIG. 15 is a cross-sectional view of the example semiconductor structure 300 in which an upper portion 1505 is formed, in accordance with various embodiments.

The upper portion 1505 may be or include silicon, doped silicon, or any other semiconductor material that can be epitaxially grown on the lower portion 915. For example, the upper portion 1505 may be the same materials as of the lower portion 915. The upper portion 1505 may have a conductive type the same as the lower portion 915. The lower portion 915 and the upper portion 1505 can define a base structure, while the upper portion 1505 provides a top hookup of the base structure and both the emitter and collector epitaxial structures 1004, 1006.

The upper portion 1505 may be formed or deposited using at least one suitable deposition technique, such as CVD, ALD, MBE, the like, or combinations thereof. For example, the upper portion 1505 can be epitaxially grown on the lower portion 915. Any portion of the upper portion 1505 and/or any material disposed over a level above the etched cap portion 1310 can be removed by a planarization process such as CMG/P. As shown, the etched cap portion 1310 and the etched dielectric 1315 can electrically isolate the upper portion 1505 from the first and second metal structures 1009, 1011.

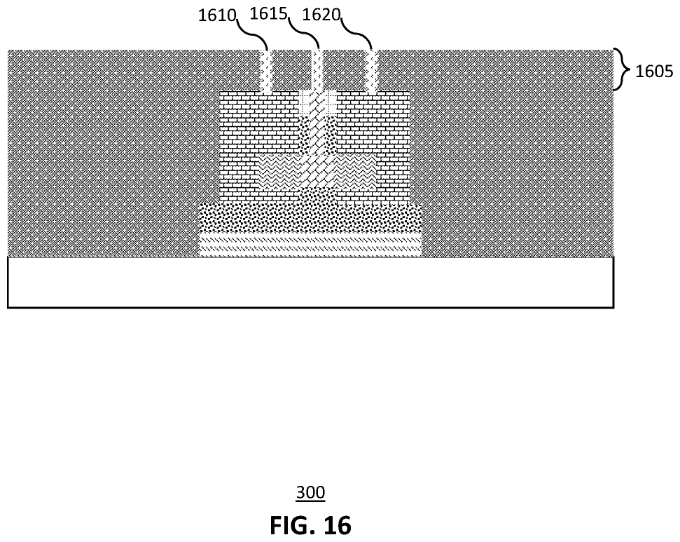

Corresponding to operation 150 of the method 100 in FIG. 1, FIG. 16 is a cross-sectional view of the example semiconductor structure 300 in which a first electrode 1610, a second electrode 1615, a third electrode 1620 are formed, in accordance with various embodiments.

The isolation structure 1605 can be formed on the surface of the structure shown in FIG. 15. The isolation structure 1605 may be or include a dielectric material the same as of the isolation structures 505. The isolation structure 1605 can be formed by any deposition process. Following the formation of the isolation structure 1605, portions for the electrodes can be etched. A mask (not shown) can define the portions for the electrodes to be etched, and conductive materials for the electrodes can be formed in the etched portions. Specifically, the electrodes 1610, 1615, 1620 are formed such that each of the electrodes 1610, 1615, 1620 can be connected to the respective epitaxial structure (e.g., the emitter and collector epitaxial structures 1004, 1006 and the upper portion 1505 of the base structure). As shown in FIG. 16, the first electrode 1610 is connected to the emitter epitaxial structure 1004, the third electrode 1620 is connected to the collector epitaxial structure 1006, and the second electrode 1615 is connected to the upper portion 1505 of the base structure. The electrodes 1610, 1615, 1620 may be formed of any metal conductor. Although depicted as one layer, the electrodes may include one or more layers. For example, the electrodes may include a first core layer for conducting and a second layer surrounding the first core layer for preventing diffusion (e.g., diffusion barrier). The electrodes 1610, 1615, 1620 can operatively serve as connection terminals for the collector, base, and emitter of a bipolar junction transistor, respectively.

The structure 300 can provide a plurality of bipolar devices each including emitter and collector regions (e.g., the emitter and collector epitaxial structures 1004, 1006) and a base region (e.g., the upper portion 1505 and the lower portion 915). The bipolar devices can be isolated from each other and from the substrate 305.

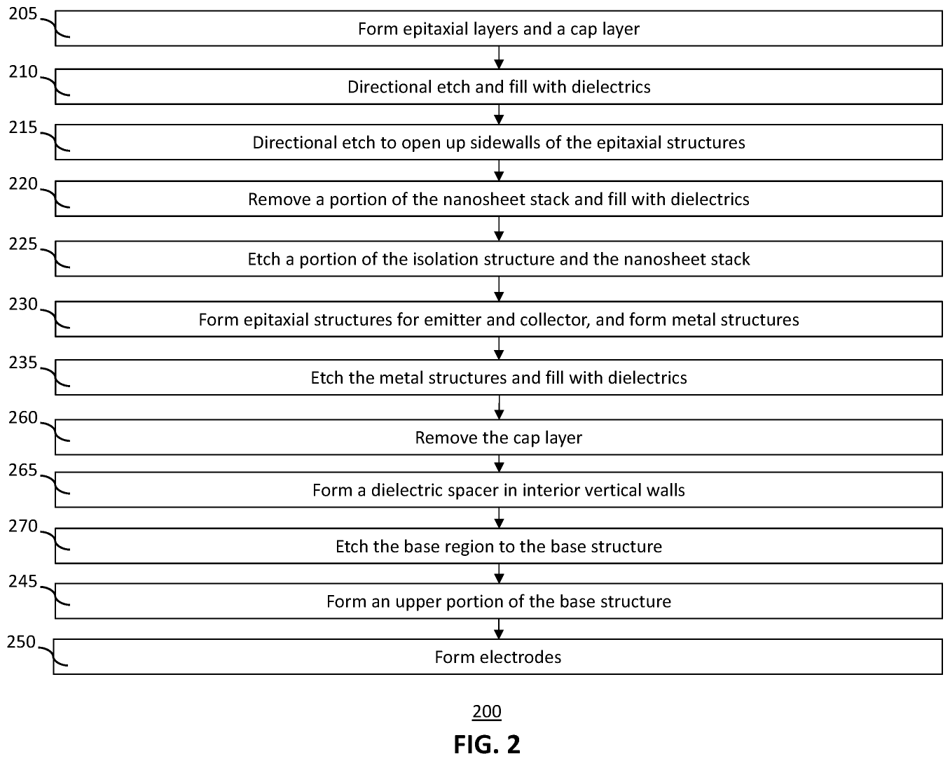

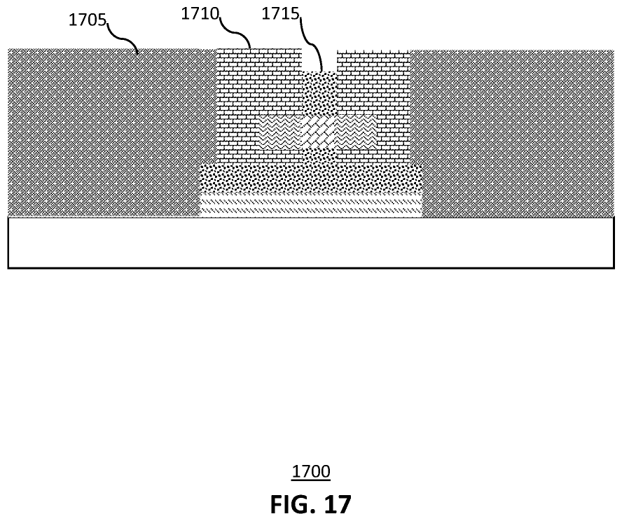

Now referring to FIG. 2, a flow chart of an example method 200 for fabricating a semiconductor device is illustrated, in accordance with some embodiments. In the method 200, operation 205 to operation 235 are substantially similar or identical to operation 105 to operation 135 of the method 100 in FIG. 1. Operation 245 and operation 250 are substantially similar or identical to operation 145 and operation 150 of the method 100 in FIG. 1. Thus, operation 260 to operation 270 are discussed here with respect to FIGS. 17 to 20. It is noted that the method 200 is merely an example and is not intended to limit the present disclosure. Accordingly, it is understood that additional operations may be provided before, during, and after the method 200 of FIG. 2, that any operation may be omitted, and that some other operations may only be briefly described herein.

In various embodiments, operations of the method 200 may be associated with cross-sectional views of an example structure at various fabrication stages as shown in FIGS. 17 to 20, which will be discussed in further detail below. It should be understood that the structure, shown in FIGS. 17 to 20, may include a number of other structures, while remaining within the scope of the present disclosure.

In brief overview, the method 200 can continue to operation 260 of removing the cap layer, from operation 235 (e.g., operation 135 of the method 100; the structure 300 shown in FIGS. 11 and 12). The method 200 can continue to operation 265 of forming a dielectric spacer in interior vertical walls. The method 200 can continue to operation 270 of etching the base region to the base structure. The method 200 can continue to operation 245 (e.g., operation 145 of the method 100; the structure 300 shown in FIG. 15), followed by operation 250 (e.g., operation 150 of the method 100; the structure shown in FIG. 16).

Corresponding to operation 260 of the method 200 in FIG. 2, FIG. 17 is a cross-sectional view of an example semiconductor structure 1700 in which a top cap layer (e.g., the cap portion 925 of the structure 300 shown in FIG. 11) is removed, in accordance with various embodiments. As shown, the structure 1700 shows isolation structures 1705 (similar or identical to the isolation structures 505 shown in FIG. 11), metal structures 1710 (similar or identical to the first and second metal structures 1009, 1011 shown in FIG. 11), and a dielectric portion 1715 (similar or identical to the dielectric portion 920 shown in FIG. 11).

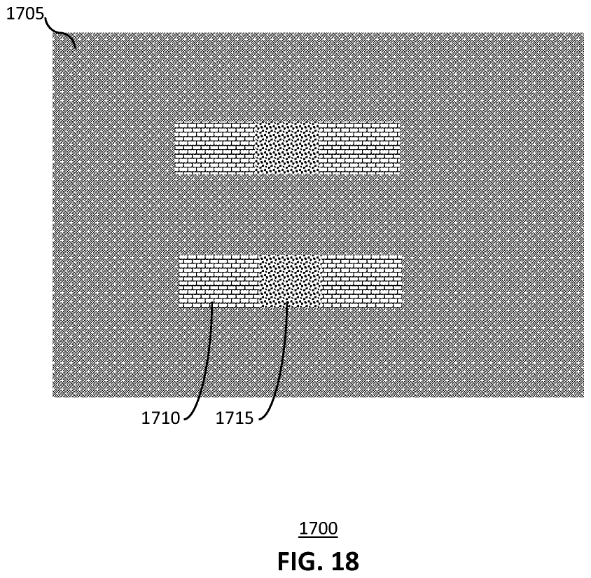

An etchant can be used to etch the top cap layer. The etchant can selectively etch the top layer without affecting and/or etching the other structures (e.g., the isolation structures 1705, the metal structures 1710, the dielectric portion 1715, etc.). For example, any of the isolation structures 1705, the metal structures 1710, or the dielectric portion 1715 may be non-reactive with the etchant. FIG. 18 is a top view of the structure 1700 depicted in FIG. 17, in accordance with various embodiments.

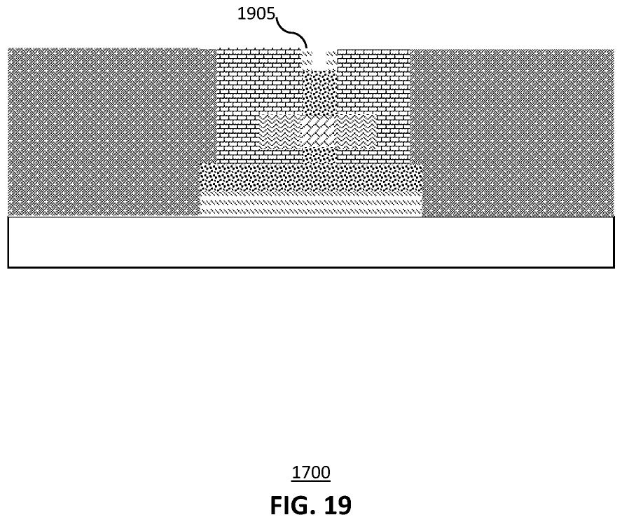

Corresponding to operation 265 of the method 200 in FIG. 2, FIG. 19 is a cross-sectional view of the example semiconductor structure 1700 in which a dielectric spacer 1905 is formed in interior vertical walls, in accordance with various embodiments.

The dielectric spacer 1905 may be or include any dielectric material. The dielectric spacer 1905 can be formed by any deposition process. The dielectric spacer 1905 may be formed or deposited using at least one suitable deposition technique, such as CVD, FCVD, ALD, the like, or combinations thereof.

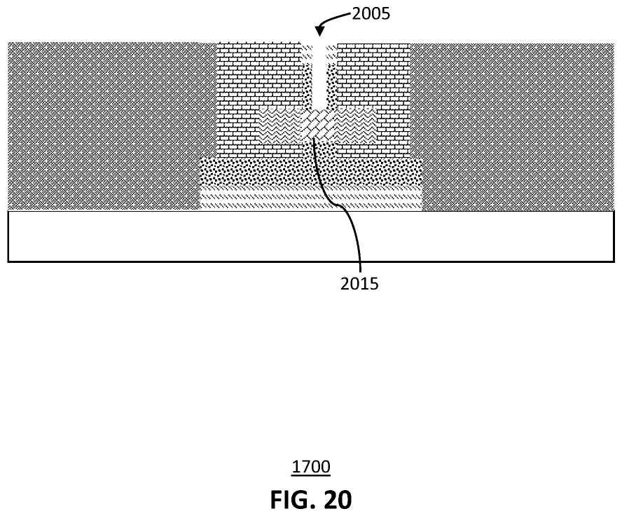

Corresponding to operation 270 of the method 200 in FIG. 2, FIG. 20 is a cross-sectional view of the example semiconductor structure 1700 in which a base region 2005 is etched, in accordance with various embodiments. The base region 2005 can be etched with the dielectric spacer 1905 serving as a mask. This allows for a maskless self-aligned process to form a vertical base epitaxial connection.

The base region 2005 can be etched to the surface of a lower portion 2015 (similar or identical to the lower portion 915). For example, the etchant can be timed to etch to the surface of the lower portion 2015, the lower portion 2015 can be non-reactive with the etchant, or an etch stop layer can be pre-disposed along a surface of the lower portion 2015. FIG. 14 is a top view of the structure 300 depicted in FIG. 13, in accordance with various embodiments. The etchant can selectively etch the base region 2005 without affecting or etching the other structures (e.g., the isolation structures 1705, the metal structures 1710, the lower portion 2015, etc.).

The method 200 now can continue to operation 245, followed by operation 250. Operation 245 and operation 250 are substantially similar to or identical to operation 145 and 150, respectively. For example, operation 245 (e.g., operation 145) can be performed on the structure 1700 shown in FIG. 20 to form an upper portion (e.g., the upper portion 1505) in the base region 2005 of the structure 1700. Subsequently, operation 250 (e.g., operation 150) can be performed to form electrodes (e.g., the electrodes 1610, 1615, 1620).

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a first semiconductor structure including a lower portion and an upper portion, wherein the first semiconductor structure has a first conductive type;
a second semiconductor structure in contact with the lower portion of the first semiconductor structure, wherein the second semiconductor structure has a second conductive type opposite to the first conductive type; and
a third semiconductor structure in contact with the lower portion of the first semiconductor structure, wherein the third semiconductor structure has the second conductive type,
wherein the second semiconductor structure and the third semiconductor structure laterally extend toward opposite directions.

2. The semiconductor device of claim 1, further comprising:
a first metal structure in electrical contact with the second semiconductor structure; and
a second metal structure in electrical contact with the third semiconductor structure.

3. The semiconductor device of claim 2, wherein the first semiconductor structure is laterally interposed between the first and second metal structures, but is electrically isolated from each of the first and second metal structures.

4. The semiconductor device of claim 3, further comprising:
a first dielectric structure extending along a first sidewall of the upper portion of the first semiconductor structure to electrically isolate the first semiconductor structure from the first metal structure; and
a second dielectric structure extending along a second sidewall of the upper portion of the first semiconductor structure to electrically isolate the first semiconductor structure from the second metal structure.

5. The semiconductor device of claim 2, wherein
the first metal structure is in contact with a top surface, a bottom surface, and a first sidewall of the second semiconductor structure; and
the second metal structure is in contact with a top surface, a bottom surface, and a first sidewall of the third semiconductor structure.

6. The semiconductor device of claim 5, wherein
the second semiconductor structure has a second sidewall opposite to its corresponding first sidewall and in direct contact with the lower portion of the first semiconductor structure; and
the third semiconductor structure has a second sidewall opposite to its corresponding first sidewall and in direct contact with the lower portion of the first semiconductor structure.

7. The semiconductor device of claim 2, further comprising:
a first contact electrode vertically extending to contact the upper portion of the first semiconductor structure;
a second contact electrode vertically extending to contact the first metal structure; and
a third contact electrode vertically extending to contact the second metal structure.

8. The semiconductor device of claim 1, wherein the first semiconductor structure, the second semiconductor structure, and the third semiconductor structure operatively serve as a base, a collector, and an emitter of a bipolar junction transistor, respectively.

9. The semiconductor device of claim 1, wherein the first semiconductor structure, the second semiconductor structure, and the third semiconductor structure are each an epitaxially grown semiconductor structure.

10. A semiconductor device, comprising:
a first semiconductor structure having a first conductive type, the first semiconductor structure comprising an upper portion and a lower portion;
a second semiconductor structure having a second conductive type opposite to the first conductive type;
a third semiconductor structure having the second conductive type,
wherein the lower portion of the first semiconductor structure is disposed between the second semiconductor structure and the third semiconductor structure and is in electrical contact with the second semiconductor structure and the third semiconductor structure.

11. The semiconductor device of claim 10, further comprising:
a first metal structure in electrical contact with the second semiconductor structure; and
a second metal structure in electrical contact with the third semiconductor structure.

12. The semiconductor device of claim 11, wherein the second semiconductor structure and the third semiconductor structure physically isolate the lower portion of the first semiconductor structure from the first metal structure and the second metal structure.

13. The semiconductor device of claim 11, further comprising:
a first dielectric structure disposed between the upper portion of the first semiconductor structure and the first metal structure; and
a second dielectric structure disposed between the upper portion of the first semiconductor structure and the second metal structure.

14. The semiconductor device of claim 11, wherein the first dielectric structure and the second dielectric structure physically isolate the upper portion of the first semiconductor structure from the first metal structure and the second metal structure.

15. The semiconductor device of claim 11, further comprising:
a first contact electrode vertically extending to contact the upper portion of the first semiconductor structure;
a second contact electrode vertically extending to contact the first metal structure; and
a third contact electrode vertically extending to contact the second metal structure.

16. The semiconductor device of claim 10, wherein a lateral dimension of the lower portion of the first semiconductor structure is greater than a lateral dimension of the upper portion of the first semiconductor structure.

17. The semiconductor device of claim 10, wherein the first semiconductor structure, the second semiconductor structure, and the third semiconductor structure are each an epitaxially grown semiconductor structure.

18. A method for fabricating semiconductor devices, comprising:
forming a lower portion of a first semiconductor structure vertically interposed between a first dielectric structure and a second dielectric structure;
epitaxially growing a second semiconductor structure and a third semiconductor structure from the lower portion of the first semiconductor structure;
forming a first metal structure and a second metal structure to contact the second semiconductor structure and the third semiconductor structure, respectively, and
forming an upper portion of the first semiconductor structure that extends through at least the second dielectric structure.

19. The method of claim 18, wherein
the first metal structure is in contact with a top surface, a bottom surface, and a first sidewall of the second semiconductor structure, the second semiconductor structure having a second sidewall in direct contact with the lower portion of the first semiconductor structure; and
the second metal structure is in contact with a top surface, a bottom surface, and a first sidewall of the third semiconductor structure, the third semiconductor structure having a second sidewall in direct contact with the lower portion of the first semiconductor structure.

20. The method of claim 18, wherein the first semiconductor structure has a first conductivity type, while the second and third semiconductor structures have a second conductive type opposite to the first conductivity type.
